(19) United States
(12) Patent Application Publication
(10) Pub. No.: US 2022/0075030 A1
(43) Pub. Date: Mar. 10, 2022

(54) Vehicle Sensor Mounting System

(71) Applicant: Motional AD LLC, Boston, MA (US)

(72) Inventors: Justin D'Antonio, Pittsburgh, PA (US); Sean Beaudette, Pittsburgh, PA (US); Dexter Stoltz, Emsworth, PA (US); Peter Brueckner, Pittsburgh, PA (US)

(21) Appl. No.: 17/016,277

(22) Filed: Sep. 9, 2020

(51) Int. Cl. G01S 7/481; B60R 11/04; G01S 17/931; H02G 3/08; H05K 7/20

(52) U.S. Cl. CPC G01S 7/4811; B60R 11/04; B60R 2011/004; H02G 3/081; H05K 7/20136; G01S 17/931

(57) ABSTRACT

A vehicle sensor mounting system includes a tubular bridge structure that spans across the width of the vehicle roof and attaches to existing rooftop anchor points. The mounting system allows camera sensors to have full field-of-view coverage while being as close to the vehicle body as possible to reduce parallax, and not being occluded by the vehicle body or mounting system. The mounting system also allows the cameras to be co-axial with a LiDAR sensor and to minimize parallax. The mounting system has a minimum natural frequency that reduces road vibrations, allowing the sensors to remain in a stable mounting position and minimizes the motion of the sensors relative to the vehicle chassis to reduce misalignment errors in the sensor data. The mounting system includes a front and rear assembly. The rear assembly includes a cable hub assembly that provides a single ingress/egress point for a multi-conductor sensor cable.

### TECHNICAL FIELD

This disclosure relates generally to mechanical structures for mounting sensors on rooftops of vehicles.

### BACKGROUND

An autonomous vehicle (AV) has many sensors that allow the vehicle to operate autonomously. These sensors typically include a light detection and ranging (LiDAR) sensor for gathering three-dimensional (3D) data (“point cloud”) and multiple radio detection and ranging (RADAR) sensors and camera sensors. The sensors are typically mounted to the rooftop of the vehicle, as well as other locations on the vehicle. The AV typically includes a perception system that detects and tracks objects in the operating environment of the AV using data from the sensors. The perception system “fuses” the sensor data to obtain a more accurate understanding of the objects in the operating environment.

It is desirable that rooftop sensors be mounted in a manner that provides a stable and secure platform for sensors, reduces the impact of road vibrations on the sensors and enhances sensor data fusion by allowing for accurate alignment of the sensors to within a desired mechanical tolerance. Additionally, it is desirable to mount rooftop sensors in a manner that does not damage the integrity of the vehicle by, for example, maintaining weather/water resistance by using existing anchor points (e.g., rails for luggage racks) to attach the mounting system to the roof of the AV to avoid drilling holes in the roof. It is also desirable to maintain service access to the sensors without removing the mounting system from the AV.

### SUMMARY

Embodiments of the vehicle sensor mounting system disclosed herein include a front assembly and rear assembly that mount to existing anchor points (e.g., raised side rails, rain gutters) on a vehicle rooftop. The front assembly includes a bridge subassembly that includes two legs and a middle section disposed between the two legs. The intersections of the legs with the middle section forms two bend angles giving the structure its “bridge” profile. The base of the tubular bridge structure (closer to the mounting locations) is wider than the middle section and the legs curve behind the middle section to ensure that forward camera sensors and LiDAR attached to the middle section have full field-of-view (FOV) coverage while being as close to the vehicle body as possible, and not occluding the cameras or LiDAR. The tubular bridge structure also allows forward and backward facing cameras to remain approximately co-axial with the LiDAR sensor and as physically close to each other as possible to minimize parallax. The tubular bridge structure is designed to have a minimum natural frequency to reduce high amplitude, broad spectrum road vibrations, which allows the sensors to remain in a stable mounting position and minimizes the motion of the sensors relative to the vehicle chassis to reduce misalignment errors in the sensor data.

The rear assembly provides mounting platforms for additional camera sensors and antennas (e.g., GPS antennas), and a cable hub assembly that provides a single, weather resistant, ingress/egress point for a multi-conductor sensor cable that provides conductors that attached to the rooftop sensors to provide a communication path for sensor data to an AV computer or other vehicle subsystems.

In an embodiment, an apparatus for mounting vehicle sensors, comprises: a bottom plate having a plurality of connected sections; and a top plate having a plurality of disconnected sections, each disconnected section of the top plate mated to a corresponding connected section of the base plate, forming a tubular bridge structure having two legs, a middle section, a first bend angle separating a first leg from the middle section and a second bend angle separating a second leg from the middle section, wherein the middle section is configured to mount a plurality of sensors.

In an embodiment, an apparatus for mounting vehicle sensors comprises: a bridge structure having two legs, a middle section, a first bend angle separating a first leg from the middle section and a second bend angle separating a second leg from the middle section, wherein the middle section is configured to mount a plurality of sensors; and a cable hub assembly coupled to the middle section, the cable hub assembly including an opening for receiving a multi-conductor sensor cable and an electrical interconnect configured to connect individual conductors of the multi-conductor sensor cable to individual sensors of the plurality of sensors.

In an embodiment, an system for mounting vehicle sensors comprises: a front bridge subassembly including: a bottom plate having a plurality of connected sections; and a top plate having a plurality of disconnected sections, each disconnected section of the top plate mated to a corresponding connected section of the bottom plate, forming a tubular bridge structure having two legs, a middle section, a first bend angle separating a first leg from the middle section and a second bend angle separating a second leg from the middle section, wherein the middle section is configured to mount a first plurality of sensors; a cooling fan disposed inside the middle section of the tubular bridge structure of the front assembly; and a rear bridge subassembly including: a second bridge structure having a set of two legs, a middle section, a first bend angle separating a first leg from the middle section and a second bend angle separating a second leg from the middle section, wherein the middle section is configured to mount a second plurality of sensors; and a cable hub assembly coupled to the middle section, the cable hub assembly including an opening for receiving a multi-conductor sensor cable and an electrical interconnect configured to connect individual conductors of the multi-conductor sensor cable to individual sensors of the first and second plurality of sensors.

Particular embodiments disclosed herein provide one or more of the following advantages. The vehicle sensor mounting system provides stable and level mounting platforms for multiple rooftop sensors, including multiple cameras, RADAR sensors and a centrally mounted LiDAR sensor. The mechanical structures of the vehicle sensor mounting system are designed to mount the sensors to within a specified mechanical tolerance to reduce misalignment errors introduced into a sensor data “fusion” process performed by vehicle computer. The structures have a minimum natural frequency to reduce the impact of road vibration on the sensors. The structures are designed to avoid damage to the vehicle rooftop and to ensure that the rooftop and the structures do not occlude the FOVs of the sensors.

The details of the disclosed embodiments are set forth in the accompanying drawings and the description below. Other features, objects and advantages are apparent from the description, drawings and claims.

### DESCRIPTION OF DRAWINGS

FIG. 1 is a perspective view of a front assembly of a vehicle sensor mounting system without a housing cover, according to an embodiment.

FIG. 2 is a bottom view of the front assembly shown in FIG. 1, according to an embodiment.

FIG. 3 is a perspective view of the front assembly shown in FIG. 1 with a cover attached, according to an embodiment.

FIG. 4 is a perspective view of a bridge subassembly of the front assembly shown in FIG. 1, according to an embodiment.

FIG. 5 is an exploded view of the bridge subassembly shown in FIG. 4, according to an embodiment.

FIG. 6 is a close-up view of a bend angle of the bridge subassembly shown in FIG. 4, according to an embodiment.

FIG. 7 is a side view of the bridge subassembly of FIG. 4 showing its tubular construction, according to an embodiment.

FIG. 8 is a perspective view of a rear assembly of the vehicle sensor mounting system, according to an embodiment.

FIG. 9 shows the rear assembly with a cover attached, according to an embodiment.

FIG. 10 is a perspective of the cable hub assembly shown in FIG. 8, according to an embodiment.

The same reference symbol used in various drawings indicates like elements.

### DETAILED DESCRIPTION

In the following detailed description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

In the drawings, specific arrangements or orderings of schematic elements, such as those representing devices, modules, instruction blocks and data elements, are shown for ease of description. However, it should be understood by those skilled in the art that the specific ordering or arrangement of the schematic elements in the drawings is not meant to imply that a particular order or sequence of processing, or separation of processes, is required. Further, the inclusion of a schematic element in a drawing is not meant to imply that such element is required in all embodiments or that the features represented by such element may not be included in or combined with other elements in some embodiments.

Further, in the drawings, where connecting elements, such as solid or dashed lines or arrows, are used to illustrate a connection, relationship, or association between or among two or more other schematic elements, the absence of any such connecting elements is not meant to imply that no connection, relationship, or association can exist. In other words, some connections, relationships, or associations between elements are not shown in the drawings so as not to obscure the disclosure. In addition, for ease of illustration, a single connecting element is used to represent multiple connections, relationships or associations between elements. For example, where a connecting element represents a communication of signals, data, or instructions, it should be understood by those skilled in the art that such element represents one or multiple signal paths (e.g., a bus), as may be needed, to affect the communication.

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

Several features are described hereafter that can each be used independently of one another or with any combination of other features. However, any individual feature may not address any of the problems discussed above or might only address one of the problems discussed above. Some of the problems discussed above might not be fully addressed by any of the features described herein. Although headings are provided, information related to a particular heading, but not found in the section having that heading, may also be found elsewhere in this description.

As used herein, the term “autonomous capability” refers to a function, feature, or facility that enables a vehicle to be partially or fully operated without real-time human intervention, including without limitation fully autonomous vehicles, highly autonomous vehicles, and conditionally autonomous vehicles.

As used herein, an autonomous vehicle (AV) is a vehicle that possesses autonomous capability.

As used herein, “vehicle” includes means of transportation of goods or people. For example, cars, buses, trains, airplanes, drones, trucks, boats, ships, submersibles, dirigibles, etc. A driverless car is an example of a vehicle.

As used herein, “trajectory” refers to a path or route to operate an AV from a first spatiotemporal location to second spatiotemporal location. In an embodiment, the first spatiotemporal location is referred to as the initial or starting location and the second spatiotemporal location is referred to as the destination, final location, goal, goal position, or goal location. In some examples, a trajectory is made up of one or more segments (e.g., sections of road) and each segment is made up of one or more blocks (e.g., portions of a lane or intersection). In an embodiment, the spatiotemporal locations correspond to real world locations. For example, the spatiotemporal locations are pick up or drop-off locations to pick up or drop-off persons or goods.

As used herein, “sensor(s)” includes one or more hardware components that detect information about the environment surrounding the sensor. Some of the hardware components can include sensing components (e.g., image sensors, biometric sensors), transmitting and/or receiving components (e.g., laser or radio frequency wave transmitters and receivers), electronic components such as analog-to-digital converters, a data storage device (such as a RAM and/or a nonvolatile storage), software or firmware components and data processing components such as an ASIC (application-specific integrated circuit), a microprocessor and/or a microcontroller.

As used herein, the phrase “one or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “includes,” and/or “including,” when used in this description, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

As used herein, an AV system refers to the AV along with the array of hardware, software, stored data, and data generated in real-time that supports the operation of the AV. In an embodiment, the AV system is incorporated within the AV. In an embodiment, the AV system is spread across several locations. For example, some of the software of the AV system is implemented on a cloud computing environment.

In general, this document describes technologies applicable to any vehicles that have one or more autonomous capabilities including fully autonomous vehicles, highly autonomous vehicles, and conditionally autonomous vehicles, such as so-called Level 5, Level 4 and Level 3 vehicles, respectively (see SAE International's standard J3016: Taxonomy and Definitions for Terms Related to On-Road Motor Vehicle Automated Driving Systems, which is incorporated by reference in its entirety, for more details on the classification of levels of autonomy in vehicles). The technologies described in this document are also applicable to partially autonomous vehicles and driver assisted vehicles, such as so-called Level 2 and Level 1 vehicles (see SAE International's standard J3016: Taxonomy and Definitions for Terms Related to On-Road Motor Vehicle Automated Driving Systems). In an embodiment, one or more of the Level 1, 2, 3, 4 and 5 vehicle systems may automate certain vehicle operations (e.g., steering, braking, and using maps) under certain operating conditions based on processing of sensor inputs. The technologies described in this document can benefit vehicles in any levels, ranging from fully autonomous vehicles to human-operated vehicles.

### System Overview

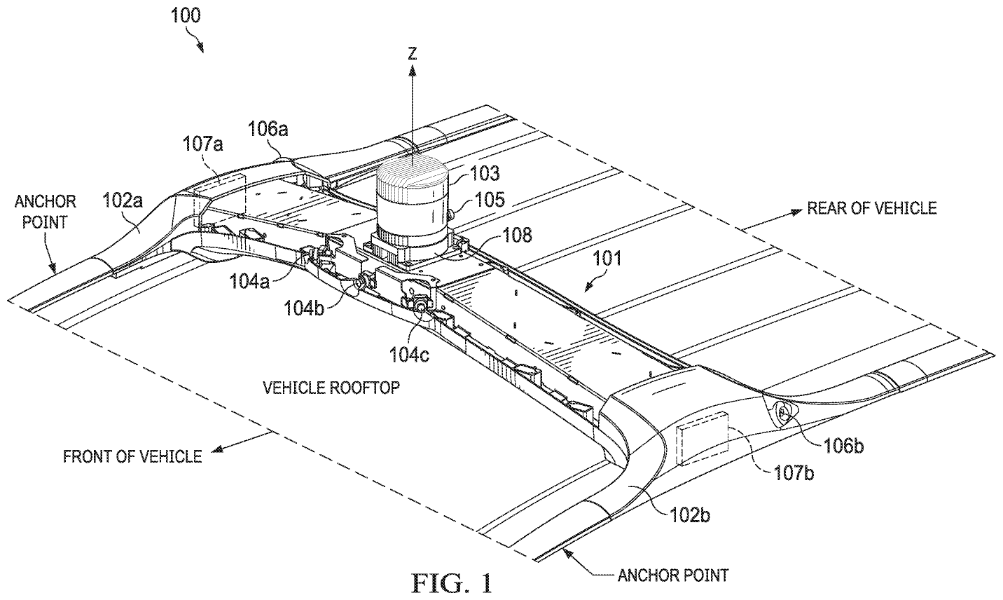

FIG. 1 is a perspective view of front assembly 100 of a vehicle sensor mounting system with sensors, according to an embodiment. Front assembly 100 includes bridge subassembly 101, mounting brackets 102a, 102b, LiDAR 103, forward facing cameras 104a-104c, backward facing camera 105, rear corner cameras 106a, 106b and RADAR sensors 107a, 107b. LiDAR 103 is shown mounted on heat sink 108. Front assembly 100 is shown mounted to existing anchor points (e.g., raised side rails, rain gutters) of a vehicle rooftop. Cameras 104a-104c, 105, 106a, 106b and RADAR sensors 107a, 107b are each fixedly attached (attached by bolts) to sensor mounting platforms of bridge subassembly 101, such that forward facing cameras 104a-104c and backward facing camera 105 are substantially co-axial with LiDAR 103.

In an embodiment, forward facing cameras 104a-104c have their boresights physically aligned to with a specified mechanical tolerance so as to ensure their respective field-of-views (FOVs) cover a desired coverage area (e.g., approximately 15 degrees of overlap on forward facing cameras 104a-104c). Rear corner cameras 106a, 106b have their boresights directed toward the right-rear and left-rear corners of the vehicle, respectively. RADAR sensors 107a, 107b have their transmitters directed to the right and left sides of the vehicle, respectively. Forward facing cameras 104a-104c are placed at locations on bridge subassembly 101 so as to minimize the physical distance between forward facing cameras 104a-104c to minimize parallax.

In an embodiment, bridge subassembly 101 is a tubular bridge structure with two legs and a middle section attached to the two legs for mounting LiDAR 103 and cameras 104a-104c, 105. Bridge subassembly 101 is mounted across the width of the vehicle rooftop. The base of bridge subassembly 101 (near mounting brackets 102a, 102b) is wider than the middle section, and the legs curve behind the middle section to avoid occlusion of forward facing cameras 104a-104c and LiDAR 103 by the vehicle and bridge subassembly 101. The ends of the right and left legs of bridge subassembly 101 insert into sleeves of mounting brackets 102a, 102b. In an embodiment, mountain brackets 102a, 102b are configured to mount to existing anchor points on the vehicle rooftop to ensure high stiffness and strength, such as factory installed raised side rails, flat tracks, fix points or rain gutters. For a “bare” roof, a clip kit can be used that includes pads and clips that fasten to the outer edges of the roof by clamping around door jams. An advantage of these attachment methods is that bridge subassembly 101 can be mounted to the vehicle rooftop without drilling holes in the rooftop, which could damage the integrity of the rooftop.

In an embodiment, bridge subassembly 101 comprises multiple plates that when mated together form the tubular bridge structure. The bridge subassembly 101 has a minimum natural frequency target (e.g., 40 Hz) to reduce the impact of road vibrations. In an embodiment, bridge subassembly 101 is comprised of sheet metal, which provides acceptable mechanical tolerances using computer numerically controlled (CNC) cut and bending processes. Sheet metal can also easily integrate PEM® brand fasteners and other geometric features as needed. Bridge subassembly 101 is designed to remain attached to the rooftop in a 50 g crash. In an embodiment, mounting accuracy of bridge subassembly 101 is about 5 mm (with locational repeatability) and about 0.5 degree, roll, pitch and yaw.

Note that bridge subassembly 101 is an example embodiment. Other embodiments can have more or fewer sensors, and the sensors can be directed in different directions and located at different positions on bridge subassembly 101 other than the directions shown in FIG. 1.

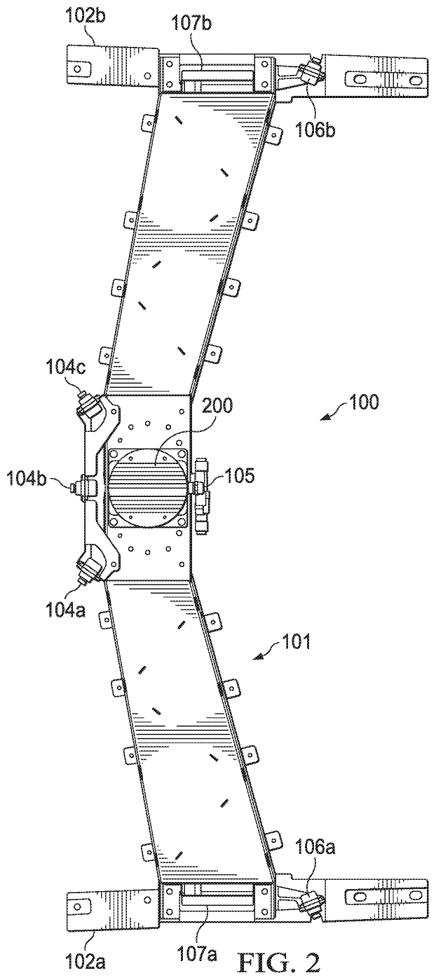

FIG. 2 is a bottom view of the front assembly 100 shown in FIG. 1, according to an embodiment. In an embodiment, a cooling fan is included inside bridge subassembly 101 (not shown) directly under LiDAR 103. The cooling fan is used to draw heat from LiDAR 103. In an embodiment, the air flow caused by the cooling fan is drawn from the bottom of bridge subassembly 101 to the top of bridge subassembly 101 and vent 200 is an air intake vent. In another embodiment, air flow is in the opposite direction and vent 200 operates as a heat exhaust vent.

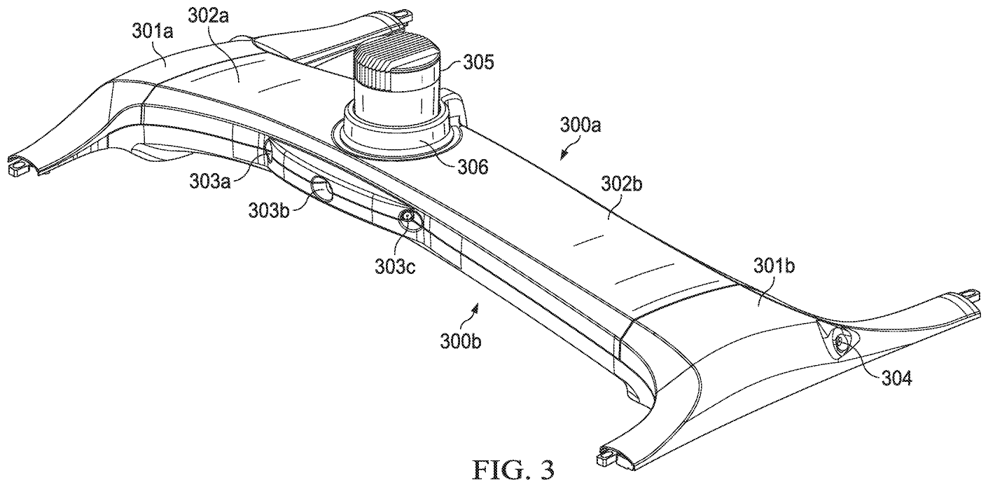

FIG. 3 is a perspective view of the front assembly 300 shown in FIG. 1 with a cover attached, according to an embodiment. The cover includes top cover 300a and bottom cover 300b. In an embodiment, top cover 300a is made of thermoplastic and includes sections 301a, 301b for covering mounting brackets 102a, 102b, respectively, top right cover 302a, top left cover 302b, LiDAR cover 304 and bezel coupling 305. When the top right/left covers 302a, 302b are attached to bottom cover 300b (e.g., attached by snap fits), portals are formed for forward cameras 104a-104c, backward facing camera 105 and rear corner cameras 106a, 106b. In an embodiment, bottom cover 300b is also made of thermoplastic and designed to be mounted to the bottom of bridge subassembly 101 and installed on the vehicle. Bezel coupling 305 allows the LiDAR 103 to be removed and replaced with a LiDAR having a different diameter. For example, a bezel coupling 305 with a smaller or adaptable diameter can be used to couple a LiDAR with a smaller diameter than LiDAR 103.

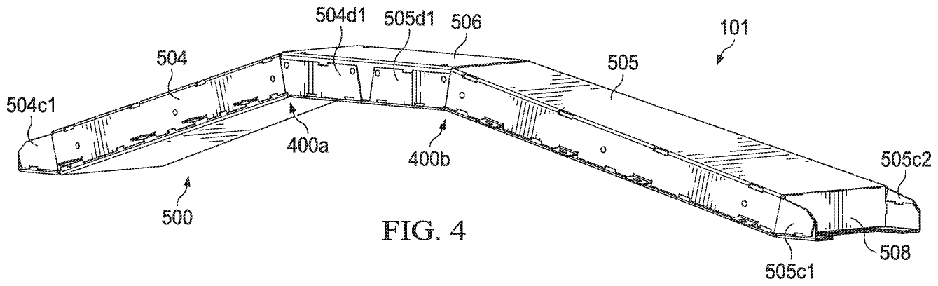

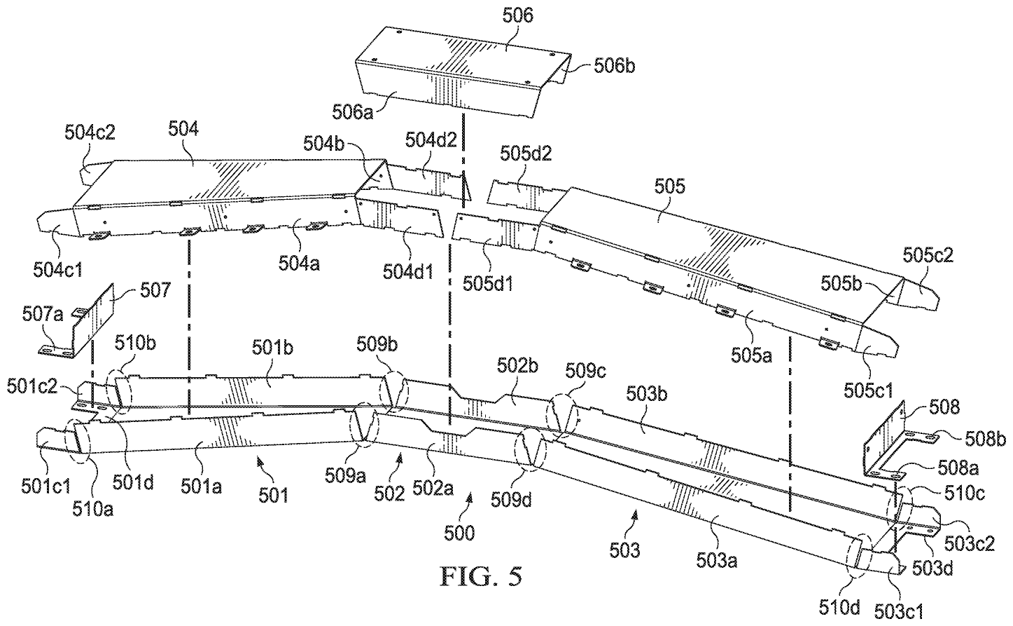

FIG. 4 is a perspective view of bridge subassembly 101 shown in FIG. 1 without the sensors or mounting brackets, according to an embodiment. Bridge subassembly 101 is a tubular bridge structure with two legs connected to a middle section. Bend angles at the intersections of the legs and middle section form a “bridge” profile. In an embodiment, the legs and middle section are comprised of multiple plates of sheet metal that are mated together, as described more fully in reference to FIG. 5.

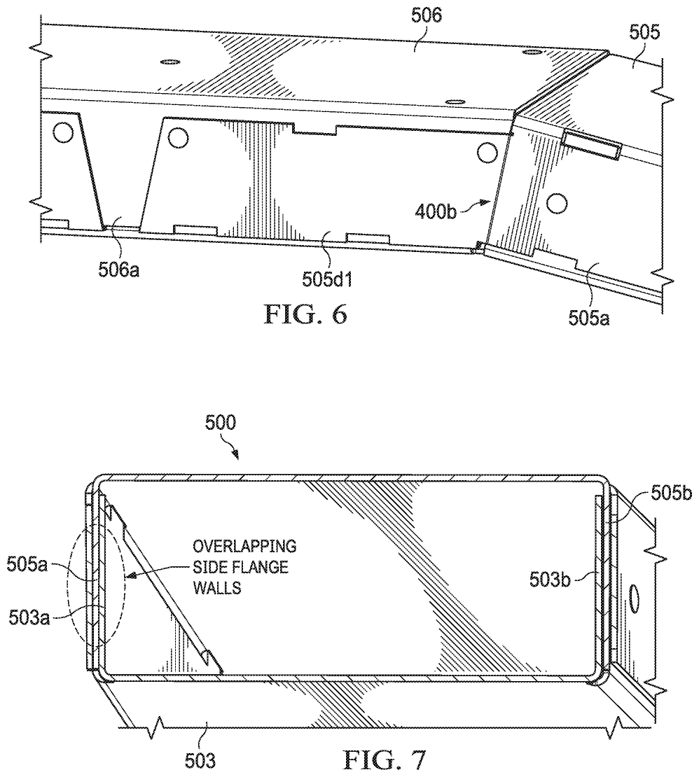

FIG. 5 is an exploded view of bridge subassembly 101 shown in FIG. 4. When the four sections shown in FIG. 5 are mated together they form bridge subassembly 101 shown in FIG. 4. Bridge subassembly 101 includes bottom plate 500, top right plate 504, top left plate 505, center plate 506, right side plate 507 and left side plate 508. Note that the terms “left” and “right” are from the perspective of a passenger facing the front of the vehicle. In an embodiment, bottom plate 500 includes three sections 501-503 fabricated from a single, continuous piece of sheet metal that provides a common datum for the other parts of bridge assembly 101. Bottom plate section 501 includes side flange walls 501a, 501b, bottom plate section 502 includes side flange walls 502a, 502b, and bottom plate section 503 includes side flange walls 503a, 503b. Triangular notches 509a-509d facilitate the making of bend angles 400a, 400b (see FIGS. 4 and 6).

As shown in FIG. 4, when the parts are mated the side flange walls 504a, 504b of top right plate 504 overlap the side flange walls 501a, 501b of bottom plate section 501, resulting in a first leg of bridge subassembly 101, as shown in FIG. 7. Similarly, the side flange walls 505a, 505b of top left plate 505 overlap the side flange walls 503a, 503b of bottom plate section 503, resulting in the second leg of bridge subassembly 101.

Center plate 506 providing the middle section of the tubular bridge structure and includes side flange walls 506a, 506b which overlap side flange walls 502a, 502b of bottom plate section 502 when in the mated configuration to form the middle section of bridge assembly 101 shown in FIG. 4. Additionally, top right plate 504 and top left plate 505 include center plate tabs 504d1, 504d2 and 505d1, 505d2, respectively. The center plate tabs 504d1, 504d2, 505d1, 505d2 overlap side flange walls 506a, 506b, respectively of center plate 106 when in the mated configuration shown in FIG. 4.

In the mated configuration, bend angles 400a, 400b are formed as shown in FIGS. 4 and 6. Bend angles 400a, 400b create the “bridge” profile with center plate 506 in the middle of the bridge to provide a level platform for LiDAR 103. Bend angles 400a, 400b allow bridge subassembly 101 to suspend above the vehicle roof to prevent damage to the rooftop. Alignment holes in in bottom plate 500, top right plate 504, top left plate 505 and center plate 506 allow for the accurate alignment during assembly of bottom plate 500 with top right plate 504, top left plate 505 and center plate 506, before the parts are fastened together at rivet and/or bolt locations.

Right side plate 507 includes tabs 507a, 507b with holes that facilitate mounting to “u-shaped” bracket 501d attached to tabs 501c1, 501c2, using any suitable fastener (e.g., rivets, PEM® brand fasteners, bolts). Left side plate 508 includes tabs 508a, 508b with holes that facilitate mounting to “u-shaped” bracket 503d attached to tabs 503c1, 503c2, using any suitable fastener (e.g., rivets, PEM® brand fasteners, bolts).

Additional notches 510a-510d between tabs 501c1, 501c2 and side flange walls 501a, 501b, and tabs 503c1, 503c2 and side flange walls 503a, 503b, respectively, facilitate bend angles at the right and left sides of bottom plate 500 so that the ends of bridge subassembly 101 are substantially level with the plane of the vehicle rooftop to facilitate their insertion into sleeves of mounting brackets 102a, 102b.

Tabs 504c1, 504c2 of top right plate 504 facilitate the mounting of RADAR sensor 107a to bridge subassembly 101, and tabs 505c1, 505c2 of top left plate 505 facilitate the mounting or RADAR sensor 107b to bridge subassembly 101.

The bridge subassembly 101 when mounted to the vehicle will be excited by high amplitude broad spectrum road vibrations encountered during normal use such a pot holes or cobblestone roads which generally occur at 30-40 hz. By raising the natural frequency of the bridge subassembly 101 above a 40 Hz minimum target the amplitude of the impulses to the sensors can be minimized, which allows the sensors to remain on a stable mounting and minimize the motion relative to the vehicle chassis. Additionally, the first modal shape of the vibration of bridge subassembly 101 is a combination of torsional or twisting motion and bending motion due to the overhanging mass and the way that the legs move rearward from the center of the structure to avoid occlusion. To reduce torsion and bending, bridge subassembly 101 is wider at its base (closer to the mounting brackets 102a, 102b) than at its center, increasing the second moment of the area for both torsion and bending. In an embodiment, a triangular brace runs through the middle section of the tubular bridge section which stiffens the top and bottom plates, minimizing deflection and raising the natural frequency of the bridge subassembly 101.

FIG. 6 is a close-up view of bend angle 400b shown in FIG. 4, according to an embodiment. Center plate tab 505d1 attached to side flange wall 505a of top left plate 505 overlaps side flange wall 506a of center plate 506 and is welded and riveted to side flange wall 506a.

FIG. 7 is a left side view of the bridge subassembly 101 showing the tubular construction, according to an embodiment. Side flange walls 505a, 505b of top left plate 505 overlap side flange walls 503a, 503b of bottom plate section 503 and are welded together at welding points.

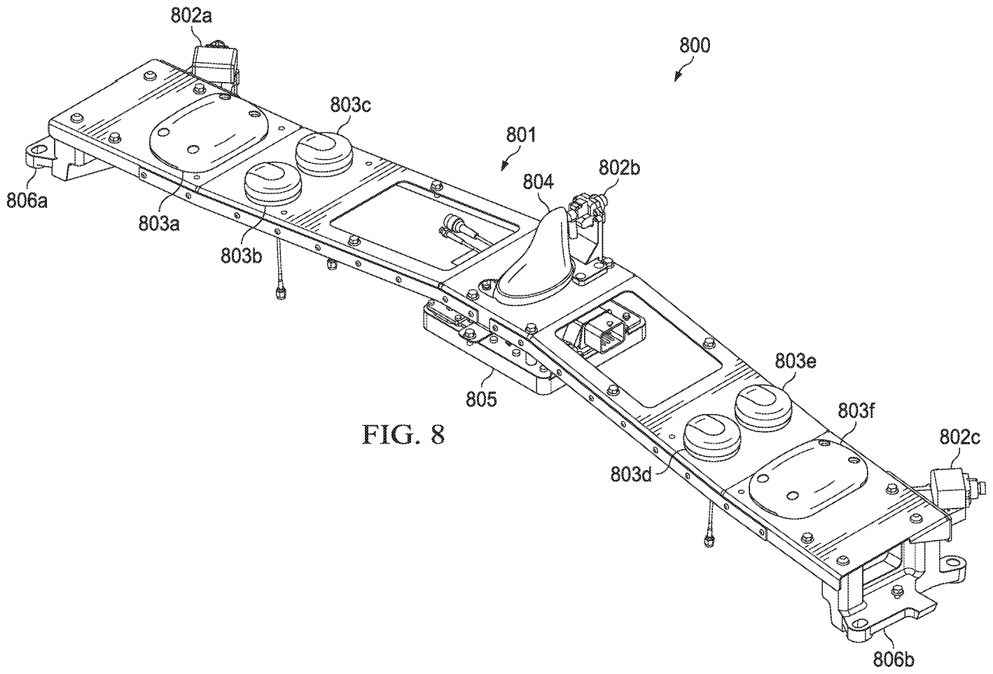

FIG. 8 is a perspective view of rear assembly 800 of the vehicle sensor mounting system, according to an embodiment. Rear assembly 800 is mounted on the roof top of the vehicle with front assembly 100, and collectively comprise the vehicle sensor mounting system. Rear assembly 800 is located toward the rear of the vehicle and is attached to existing rooftop anchor points (e.g., rails, rain gutters) of the vehicle using mounting blocks 806a, 806b.

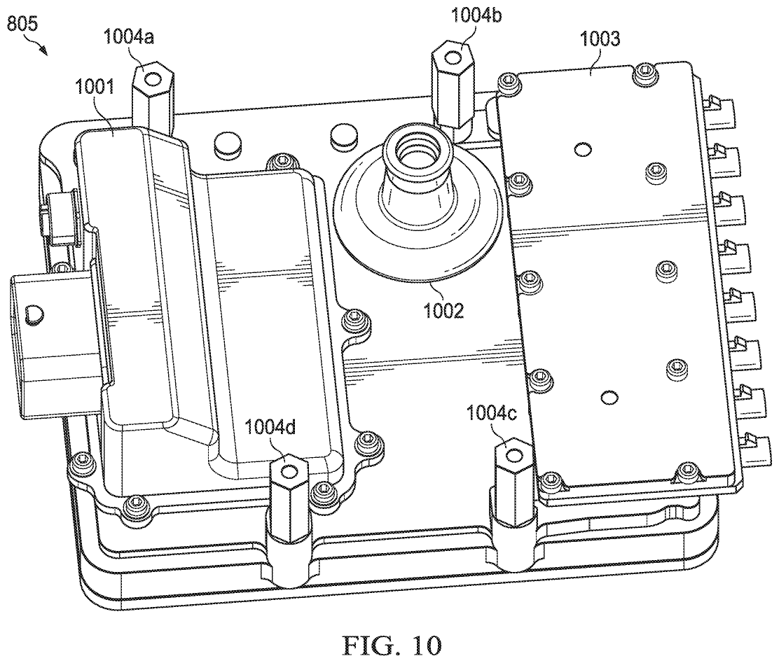

Rear assembly 800 includes bridge subassembly 801 that includes two legs and a middle section similar to bridge subassembly 101. In an embodiment, bridge subassembly is made of aluminum. Bridge subassembly 800 includes five disconnected plates. Each leg is comprised of two plates and the middle section includes a single plate. The plate for the middle section provides a level mounting platform for center backward camera 802b and dedicated short range communication (DSRC) antenna 804. The plates for the legs provide platforms for Global Position System (GPS) antennas 803a-803f. Mounting blocks 806a, 806b provide mounting platforms for rear corner cameras 802a, 802c. Underneath the middle section plate is cable hub assembly 805, which is described more fully in reference to FIG. 10.

Note that bridge subassembly 800 is an example embodiment. Other embodiments can have more or fewer sensors, and the sensors can be directed in different directions and located at different positions on bridge subassembly 800 other than the directions shown in FIG. 8.

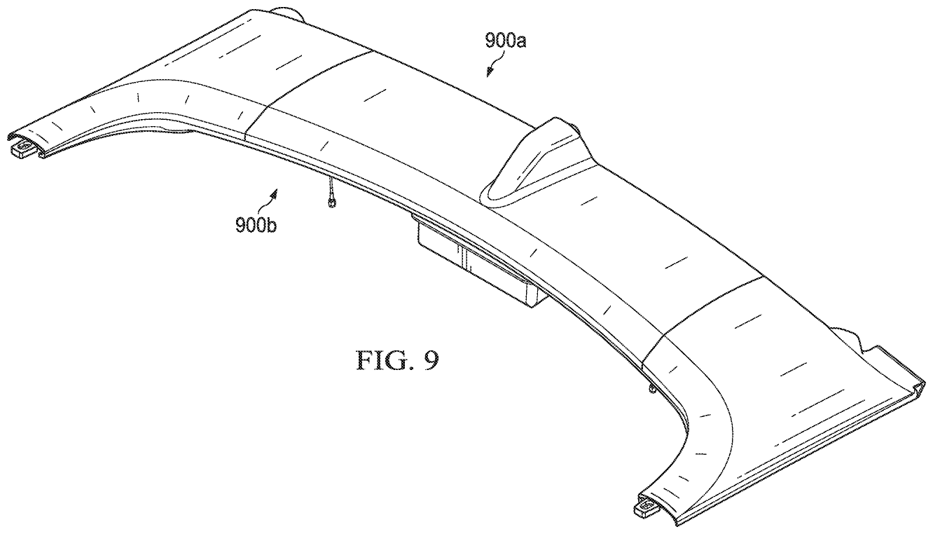

FIG. 9 shows the rear assembly with its cover attached, according to an embodiment. Like front assembly 100, rear assembly 800 has top cover 900a and bottom cover 900b. Bottom cover 900b is attached to bridge subassembly 801 (e.g., using machine screws) and mounted to the vehicle rooftop. Top cover 900 includes multiple sections that can be removed for service access without removing the entire rear assembly 800 from the vehicle rooftop.

FIG. 10 is a perspective of the cable hub assembly 805 shown in FIG. 8, according to an embodiment. Cable hub assembly 805 is positioned over an existing opening in the vehicle rooftop (used for rooftop antenna found on most modern cars) and provides a single point of ingress/egress for a multi-conductor sensor cable for communicating sensor data from the rooftop sensors. Cable hub assembly 805 mounts underneath bridge assembly 801 using four mounting posts 1004a-1104d and machine screws. Gasket 1002 provides a water-resistance seal around the multiconductor cable. Interface 1001 (e.g., a PH2.0-5P interface) provides power and a data communication path for LiDAR 103. Interface 1001 can also include power circuitry, such as transformers, inverters, filters and voltage regulators. Interconnect 1003 provides an electrical interconnect for the individual conductors of the multi-conductor sensor cable (not shown) in the vehicle sensor cable (not shown) to be attached to the individual rooftop sensors.

In the foregoing description, embodiments of the invention have been described with reference to numerous specific details that may vary from implementation to implementation. The description and drawings are, accordingly, to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims. In addition, when we use the term “further including,” in the foregoing description or following claims, what follows this phrase can be an additional step or entity, or a sub-step/sub-entity of a previously-recited step or entity.

What is claimed is:

1. An apparatus for mounting vehicle sensors, comprising:
a bottom plate having a plurality of connected sections; and
a top plate having a plurality of disconnected sections, each disconnected section of the top plate mated to a corresponding connected section of the base plate, forming a tubular bridge structure having two legs, a middle section, a first bend angle separating a first leg from the middle section and a second bend angle separating a second leg from the middle section, wherein the middle section is configured to mount a plurality of sensors.

2. The apparatus of claim 1, wherein the plurality of connected sections and disconnected sections each have opposing side flange walls, and the side flange walls of the disconnected sections overlap the side flange walls of their respective corresponding connected sections to form the tubular bridge structure.

3. The apparatus of claim 1, wherein the disconnected top plate sections on either side of the middle section have tabs that overlap the side flange walls of the middle section.

4. The apparatus of claim 1, wherein the middle section is configured to mount a light detection and ranging (LiDAR) sensor and multiple camera sensors that are co-axially aligned.

5. The apparatus of claim 4, wherein the middle section includes a bezel coupling for attaching the LiDAR sensor to the middle section.

6. The apparatus of claim 4, wherein the middle section is configured for attaching a heat sink for the LiDAR sensor.

7. The apparatus of claim 4, wherein the middle section is configured to mount the multiple camera sensors proximate to the vehicle body, such that the respective field-of-views (FOVs) of the camera sensors overlap by a specified amount, and the FOVs of the camera sensors and LiDAR are not occluded by the body of the vehicle or the apparatus.

8. The apparatus of claim 4, further comprising:
a cooling fan inside the top plate middle section configured to remove heat generated by the LiDAR sensor.

9. The apparatus of claim 1, further comprising:
two mounting brackets each having a sleeve for receiving one end of the tubular bridge structure, the mounting brackets configured to mount the apparatus to anchor points on opposite sides of a vehicle rooftop.

10. The apparatus of claim 9, wherein each end of the bottom plate has tabs and additional bending angles that facilitate insertion of ends of the tubular bridge structure into the sleeves of the mounting brackets.

11. The apparatus of claim 1, wherein the top plate and the bottom plate are made of sheet metal.

12. The apparatus of claim 1, further comprising side plates attached to opposite ends of the tubular bridge structure and are configured for mounting RADAR sensors.

13. The apparatus of claim 1, further comprising a cover for the apparatus that includes multiple disconnected sections that can be removed to provide service access to sensors.

14. The apparatus of claim 1, wherein the legs of the tubular bridge structure curve behind the middle section.

15. The apparatus of claim 1, wherein the tubular bridge structure is wider at its base than at the middle section.

16. The apparatus of claim 1, wherein the tubular bridge structure is configured to have a minimum natural frequency of about 40 Hz.

17. An apparatus for mounting vehicle sensors, comprising:
a bridge structure having two legs, a middle section, a first bend angle separating a first leg from the middle section and a second bend angle separating a second leg from the middle section, wherein the middle section is configured to mount a plurality of sensors; and
a cable hub assembly coupled to the middle section, the cable hub assembly including an opening for receiving a multi-conductor sensor cable and an electrical interconnect configured to connect individual conductors of the multi-conductor sensor cable to individual sensors of the plurality of sensors.

18. The apparatus of claim 17, wherein the bridge structure comprises five disconnected metal plates, wherein each leg is comprised of two plates and the middle section is comprised of a single plate.

19. The apparatus of claim 17, wherein the plate for the middle section provides a level mounting platform for at least one camera and at least one antenna, and the plates of the legs provide level mounting platforms for at least one antenna.

20. A system for mounting vehicle sensors, comprising:
a front assembly including:
a bottom plate having a plurality of connected sections; and
a top plate having a plurality of disconnected sections, each disconnected section of the top plate mated to a corresponding connected section of the bottom plate, forming a tubular bridge structure having two legs, a middle section, a first bend angle separating a first leg from the middle section and a second bend angle separating a second leg from the middle section, wherein the middle section is configured to mount a first plurality of sensors;
a cooling fan disposed inside the middle section of the tubular bridge structure of the front assembly; and
a rear assembly including:
a second bridge structure having a set of two legs, a middle section, a first bend angle separating a first leg from the middle section and a second bend angle separating a second leg from the middle section, wherein the middle section is configured to mount a second plurality of sensors; and
a cable hub assembly coupled to the middle section, the cable hub assembly including an opening for receiving a multi-conductor sensor cable and an electrical interconnect configured to connect individual conductors of the multi-conductor sensor cable to individual sensors of the first and second plurality of sensors.
